(19) United States
(12) Patent Application Publication
(10) Pub. No.: US 2024/0117482 A1
(43) Pub. Date: Apr. 11, 2024

(54) METHOD FOR PRODUCING SEPARATOR

(71) Applicant: TOYOTA JIDOSHA KABUSHIKI KAISHA, Toyota-shi (JP)

(72) Inventor: Hitoshi TANINO, Toyota-shi (JP)

(73) Assignee: TOYOTA JIDOSHA KABUSHIKI KAISHA, Toyota-shi (JP)

(21) Appl. No.: 18/483,186

(22) Filed: Oct. 9, 2023

(30) Foreign Application Priority Data
Oct. 11, 2022 (JP) 2022-162879

(51) Int. Cl. C23C 14/02; C09K 13/04; H01M 8/0228

(52) U.S. Cl. CPC C23C 14/021; C09K 13/04; H01M 8/0228

(57) ABSTRACT

To provide a method for producing a separator that can suppress the generation of PVD film imperfections. A method for producing a separator for fuel cells, wherein a substrate of the separator comprises a metal material; wherein the method comprises: press-forming the substrate into a separator shape, washing the substrate with an acid, and forming an electroconductive film on a surface of the acid-washed substrate by physical vapor deposition; and wherein, in the acid washing, at least one surface of the substrate is dissolved in a thickness range of from 0.49 μm to 5.00 μm.

This application claims priority to Japanese Patent Application No. 2022-162879 filed on Oct. 11, 2022, incorporated herein by reference in its entirety.

### TECHNICAL FIELD

The disclosure relates to a method for producing a separator.

### BACKGROUND

Various studies have been made on separators as disclosed in Patent Literature 1.
Patent Literature 1: Japanese Patent Application Laid-Open (JP-A) No. 2021-026839

To achieve the required corrosion resistance and conductivity of a separator for a fuel cell based on a metallic material such as stainless steel, a surface treatment such as physical vapor deposition (PVD) is usually performed on a substrate pressed into a separator shape. However, the surface of the pressed substrate is roughened due to sliding or the like between the substrate and the mold during pressing; there are scratches and the like; and defects occur in the physical vapor deposition film due to the physical vapor deposition process. As a result, there is a possibility that a separator having sufficient corrosion resistance is not obtained.

### SUMMARY

The disclosure was achieved in light of the above circumstances. An object of the disclosure is to provide a method for producing a separator capable of suppressing generation of a defective PVD film.

The method for producing the separator for fuel cells of the present disclosure is a method for producing a separator for fuel cells,
wherein a substrate of the separator comprises a metal material;
wherein the method comprises:
press-forming the substrate into a separator shape,
washing the substrate with an acid, and
forming an electroconductive film on a surface of the acid-washed substrate by physical vapor deposition; and
wherein, in the acid washing, at least one surface of the substrate is dissolved in a thickness range of from 0.49 μm to 5.00 μm.

In the method of the present disclosure, the acid may contain at least hydrochloric acid, and a concentration of the hydrochloric acid in the acid may be 4% by mass or more and 10% by mass or less.

The method further may comprise: washing the substrate with water after the acid washing and before the formation of the electroconductive film, and drying the substrate after the water washing.

The method further may comprise: performing at least one of alkali cleaning and hydrocarbon cleaning on the substrate, thereby removing oil from the surface of the substrate, after the press-forming and before the acid washing.

In the method of the present disclosure, in the acid washing, the substrate may be immersed in the acid for 10 minutes or less; the acid may be hydrochloric acid; a concentration of the hydrochloric acid in the acid may be 4% by mass or more; the metal material may be a stainless-steel alloy; and the electroconductive film may be a two-layered film composed of a titanium film and a carbon film.

The present disclosure can provide the method for producing the separator capable of suppressing generation of the defective PVD film.

### BRIEF DESCRIPTION OF THE DRAWINGS

In the accompanying drawings,

FIG. 1 shows an exemplary scanning electron-microscope (SEM) image of the surface of a pressed substrate;

FIG. 2 shows an exemplary SEM image of a cross-section of a separator in which a PVD film is formed on a pressed substrate without acid-treatment;

FIG. 3 shows an exemplary SEM image of the surface of an acid-treated substrate after pressing; and

FIG. 4 shows a graph showing the relationship between the thickness of a part of the separator, which is dissolved from the surface of the separator and the amount of iron eluted from the separator.

### DETAILED DESCRIPTION

The method for producing the separator for fuel cells of the present disclosure is a method for producing a separator for fuel cells,
wherein a substrate of the separator comprises a metal material;
wherein the method comprises:
press-forming the substrate into a separator shape,
washing the substrate with an acid, and
forming an electroconductive film on a surface of the acid-washed substrate by physical vapor deposition; and
wherein, in the acid washing, at least one surface of the substrate is dissolved in a thickness range of from 0.49 μm to 5.00 μm.

When a physical vapor deposition process is performed on a pressed substrate to form a PVD film on the substrate, PVD film is defective in the prior art.

In the prior art, adjustment of the surface roughness of the substrate is performed by polishing, but any of electropolishing, chemical polishing, and physical polishing is not realistic as a mass production technique from the viewpoint of cost and quality. In the electropolishing, since the area which can be processed at one time is small, the cost is high in mass production of the separator, which is not realistic. Chemical polishing requires a building bath for each treatment and generates a large amount of waste liquid, which is not realistic due to high cost in mass production of separators. In physical polishing, dimensional accuracy of a component is deteriorated, and it is not realistic to deal with mass production when the polishing time is taken into consideration.

Also, the surface roughness of the substrate is not a major cause of the defects. Even if the surface roughness of the base material is high to some extent, PVD film is formed so as to follow the surface roughness.

When PVD film is formed, the material on the surface of the base material is plastically flowed due to severe sliding between the base material and the mold. The main causes of the defect are roughness of the pile shape or the eaves shape generated by the plastic flow, deterioration of the surface of the mold, and roughness such as scratches generated due to roughness of the surface of the mold.

Therefore, even if the surface roughness of the base material satisfies the predetermined roughness, it is not possible to sufficiently suppress the generation of PVD film if these causes remain.

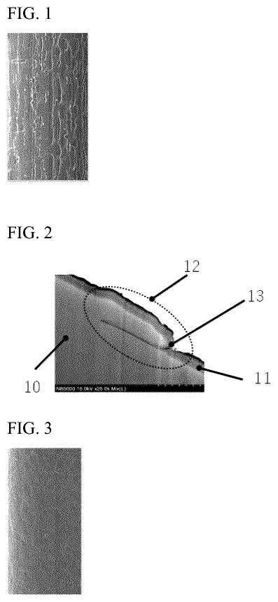

FIG. 1 shows an exemplary scanning electron-microscope (SEM) image of the surface of a pressed substrate.

FIG. 2 shows an exemplary SEM image of a cross-section of a separator in which a PVD film is formed on a pressed substrate without acid-treatment.

As shown in FIG. 1, the surface of the pressed substrate is rough. As shown in FIG. 2, when the roughness 12 is present on the base material 10, PVD film 11 is defective 13. In PVD process, a film-forming material is flown from a vapor deposition source toward a substrate. When the surface of the base material is rough as shown in FIG. 1, as shown in FIG. 2, the film forming material does not reach the rough portion and is not formed.

When a PVD film is formed to a thickness of several micrometers or more, the film is formed so as to cover the entire roughened portion, and generation of erosion is suppressed, but PVD film is not realistic in view of cost-effectiveness. Further, even in this case, cracks tend to occur in PVD film during expansion and shrinkage due to stresses at the time of assembling the component or thermal expansion and shrinkage at the time of use of the component, and the cracks become a starting point of erosion.

FIG. 3 shows an exemplary SEM image of the surface of an acid-treated substrate after pressing. After pressing as shown in FIG. 3, the surface of the acid-treated substrate is removed from the surface of the substrate due to defects in PVD film such as roughness.

According to the present disclosure, it is possible to improve the corrosion resistance of the separator by performing acid treatment on the surface of the pressed substrate to remove the cause of the occurrence of defects, and then performing physical vapor deposition treatment.

PVD film is not required to be thicker than required by dissolving the base material to a predetermined thickness or more from the surface and removing the source of the defects, and deterioration of the component dimensions can be prevented. The acid treatment can be carried out at a lower cost than the polishing treatment because a large amount of the acid treatment can be carried out in a compact facility with a treatment time of about 1 to 2 minutes or less.

The method of the present disclosure is performed in the order of a press forming step, an acid cleaning step, and a physical vapor deposition step.

The method of the present disclosure may be performed in the order of a press forming step, an oil removing step, an acid cleaning step, a water cleaning step, a drying step, and a physical vapor deposition step.

The method of the present disclosure includes a press forming step.

The press-forming step is a step of press-forming the base material into the shape of the separator.

The substrate of the separator comprises a metallic material.

The metallic material may be iron, aluminum, aluminum alloys, stainless steel (SUS), and the like.

The shape of the separator may be rectangular, oblong hexagonal, oblong 8-angled, circular, oval, or the like.

Examples of the method of press forming include a method of pressing a base material with a separator-shaped mold and molding the base material.

The method of the present disclosure may include an oil removal step.

The oil removal step is a step of removing oil from the surface of the substrate by performing at least one of alkali cleaning and hydrocarbon cleaning on the substrate after press forming and before washing with an acid. After press forming, if there is oil on the surface of the substrate and there is a concern that the acid treatment quality is affected, the oil cleaning step may be performed.

The production method of the present disclosure includes an acid washing step.

The acid cleaning step is a step of cleaning the substrate with an acid.

In acid cleaning, at least one side of the substrate is dissolved from the surface to a thickness of 0.49 μm to 5.00 μm. The thickness may have an upper limit of 2.55 μm or less. In the washing with an acid, at least one side of the substrate may be washed with an acid, and both sides may be washed with an acid.

The thickness of the surface roughness of the substrate by pressing is less than 0.49 μm, in order to remove the surface roughness it is necessary to dissolve and remove the substrate 0.49 μm or more. The thickness of the substrate prior to acid-cleaning is, for example, 0.02 mm to 0.4 mm, and may be less than or equal to 0.1 mm. One side is removed by dissolving 5.00 μm or more, or both sides are removed by dissolving 10.00 μm or more, the strength of the separator decreases when the plate thickness decreases.

In the washing with an acid, the substrate may be immersed in the acid for 10 minutes or less, or may be immersed for 0.5 minutes or more.

In the washing with acid, the temperature of the acid may be from 25° C. to 35° C.

The acid may be, for example, hydrochloric acid, nitric acid, sulfuric acid, hydrofluoric acid, and the like. The acid may comprise at least hydrochloric acid and the acid may be hydrochloric acid. Hydrochloric acid can be handled safely compared to nitric acid, sulfuric acid, and hydrofluoric acid.

The concentration of hydrochloric acid in the acid may be 4% by mass or more and 10% by mass or less. The concentration of hydrochloric acid as acid may be 4% by mass or more, 10% by mass or less, or 8% by mass or less. When the hydrochloric acid concentration is less than 4% by mass, the solubility is weak, and the immersion time is prolonged. Handling is easy if the hydrochloric acid concentration is 10% by mass or less.

The method of the present disclosure may include a water washing step.

The water washing step is a step of washing the substrate with water after washing with an acid and before forming the conductive film.

The method of the present disclosure may include a drying step.

The drying step is a step of drying the substrate after washing with the water.

The method of the present disclosure includes a physical vapor deposition process.

The physical vapor deposition step is a step of forming a conductive film by physical vapor deposition on the surface of the substrate that has been cleaned with the acid.

Physical vapor deposition may include sputtering, ion plating, and the like.

The conductive coating may be a titanium coating, a carbon coating, or the like. The formed titanium coating improves the corrosion resistance of the separator. The carbon coating improves the conductivity of the separator. The thickness of the conductive coating may be 0.01 μm or more and 1 μm or less.

The conductive coating may be a two-layer coating consisting of a titanium coating and a carbon coating. In the conductive coating, a titanium coating and a carbon coating may be formed in order from the base material side.

The material of the titanium coating may include pure titanium or a titanium alloy.

The film thickness of the titanium film may be, for example, 10 nm to 1000 nm.

The carbon film may be formed by, for example, the physical vapor deposition method described above using carbon as a target. Examples of the material of the carbon film include carbon black. The thickness of the carbon coating may be, for example, 10 nm to 1000 nm.

The separator of the present disclosure is for fuel cells.

The fuel cell may include only one unit cell of the fuel cell, or may be a fuel cell stack in which a plurality of unit cells are stacked.

In the present disclosure, both the unit cell and the fuel cell stack of the fuel cell may be referred to as a fuel cell.

The number of stacked unit cells of the fuel cell is not particularly limited, and may be, for example, 2 to several hundred.

The single cell of the fuel cell may include two separators sandwiching the membrane electrode gas diffusion layer assembly and the membrane electrode gas diffusion layer assembly.

The membrane electrode gas diffusion layer assembly includes an anode-side gas diffusion layer, an anode catalyst layer, an electrolyte membrane, a cathode catalyst layer, and a cathode-side gas diffusion layer in this order.

The cathode (oxidant electrode) includes a cathode catalyst layer and a cathode-side gas diffusion layer.

The anode (fuel electrode) includes an anode catalyst layer and an anode-side gas diffusion layer.

In the present disclosure, the reaction gas supplied to the anode is a fuel gas (anode gas), and the reaction gas supplied to the cathode is an oxidant gas (cathode gas). The fuel gas is a gas mainly containing hydrogen, and may be hydrogen. The oxidizing gas is a gas containing oxygen, and may be air or the like.

The two separators are one anode-side separator and the other cathode-side separator. In the present disclosure, the anode-side separator and the cathode-side separator are collectively referred to as a separator.

The separator of the present disclosure may be used as an anode-side separator or a cathode-side separator.

### EXAMPLES

### Example 1

(1) A SUS304 plate having a thickness 0.1 mm was press-molded as a base material, and the base material was formed into a separator-like shape.
(2) Hydrocarbon cleaning was performed to remove the surface oil content of the substrate.
(3) Acid treatment was carried out under the conditions shown in Table 1.
(4) By PVD device, a two-layer film of a PVD film composed of a titanium-coated film (thickness 150 nm) and a carbon-coated film (30 nm) was formed on the surface of the substrate in order from the substrate side. Thus, a separator was obtained.
(5) Corrosion test by potentiostatic test (iron elution measurement) was carried out.

### Potentiostatic Test Conditions

A sample of 4 cm×5 cm was cut from the separators in the power generation area, and the sample was immersed in an electrolyte solution. By electrically connecting the counter electrode made of a platinum plate and the sample (sample electrode) while the sample was immersed in the electrolyte solution, a potential difference of 0.9V was generated between the counter electrode and the sample electrode, and the sample was corroded. During the test, the potential of the sample was held constant at the reference electrode.
Electrolyte: sulfuric acid (pH3), chlorine 10 ppm, fluorine 3 ppm
Test temperature: 80° C.
Applied potential: 0.9V vs SHE (standard-hydrogen-electrode)
Test time: 60 hours
(6) The electrolytic solution after the test was collected, and the iron components eluted in the electrolytic solution were measured using an inductively coupled plasma (ICP) emission spectrometer. On the basis of the measured values obtained, the elution amounts of iron (Fe) per 1 cm 2 of the evaluated area of the samples at 1 hour of the test were calculated. The results obtained are shown in Table 1.

### Comparative Example 1

A separator was obtained under the same conditions as in Example 1 except that no acid treatment was performed, and a constant potential test was performed.

### Comparative Example 2, Examples 2 to 9

A separator was obtained under the same conditions as in Example 1 except that acid treatment was performed under the conditions shown in Table 1, and a constant potential test was performed.

TABLE 1

| | Hydrochloric acid | Hydrochloric acid | | Dissolution | |
|---|---|---|---|---|---|
| | concentration | temperature | Immersion time | thickness | Iron elution |
| | (%) | (° C.) | (Minutes) | (μm/Single Side) | (×10⁻¹⁰ mol/cm²/hr) |
| Comparative | — | — | — | 0 | 2.70 |
| Example 1 | | | | | |
| Comparative | 4 | 25 | 1 | 0.17 | 2.01 |
| Example 2 | | | | | |
| Example 1 | 4 | 25 | 10 | 1.52 | 0.30 |
| Example 2 | 4 | 25 | 2 | 0.49 | 0.27 |
| Example 3 | 4 | 35 | 2 | 1.00 | 0.34 |
| Example 4 | 6 | 25 | 1 | 0.55 | 0.48 |
| Example 5 | 6 | 25 | 2 | 1.17 | 0.40 |
| Example 6 | 6 | 35 | 0.5 | 0.60 | 0.45 |
| Example 7 | 6 | 35 | 1 | 1.24 | 0.38 |
| Example 8 | 6 | 35 | 2 | 2.55 | 0.30 |
| Example 9 | 8 | 35 | 0.5 | 0.92 | 0.43 |

### [Evaluation Results]

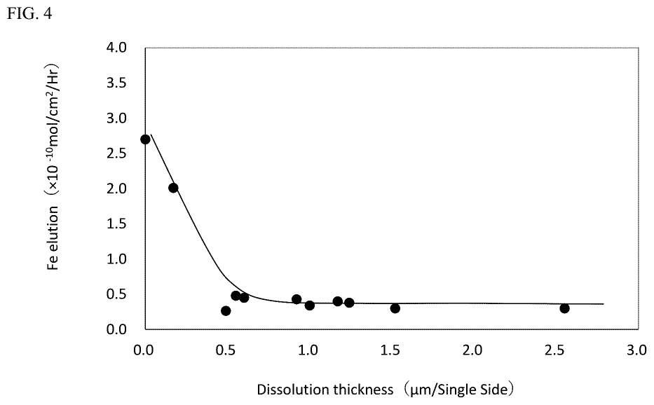

FIG. 4 shows a graph showing the relationship between the thickness of a part of the separator (Dissolution thickness), which is dissolved from the surface of the separator and the amount of iron eluted from the separator.

As shown in Table 1 and FIG. 4, by dissolving a part of the separator with a thickness of 0.49 μm or more from the surface of the separator, it is possible to suppress the generation of defects of PVD film, very excellent corrosion resistance was obtained with iron-eluting amount of 0.48×10⁻¹⁰ mol/cm²/hr or less.

### REFERENCE SIGNS LIST

10 Substrate
11 PVD film
12 Roughness
13 Defect

1. A method for producing a separator for fuel cells,
wherein a substrate of the separator comprises a metal material;
wherein the method comprises:
press-forming the substrate into a separator shape,
washing the substrate with an acid, and
forming an electroconductive film on a surface of the acid-washed substrate by physical vapor deposition; and
wherein, in the acid washing, at least one surface of the substrate is dissolved in a thickness range of from 0.49 μm to 5.00 μm.

2. The method for producing the separator according to claim 1,
wherein the acid contains at least hydrochloric acid, and
wherein a concentration of the hydrochloric acid in the acid is 4% by mass or more and 10% by mass or less.

3. The method for producing the separator according to claim 1, the method further comprising:
washing the substrate with water after the acid washing and before the formation of the electroconductive film, and
drying the substrate after the water washing.

4. The method for producing the separator according to claim 1, the method further comprising:
performing at least one of alkali cleaning and hydrocarbon cleaning on the substrate, thereby removing oil from the surface of the substrate, after the press-forming and before the acid washing.

5. The method for producing the separator according to claim 1,
wherein, in the acid washing, the substrate is immersed in the acid for 10 minutes or less;
wherein the acid is hydrochloric acid;
wherein a concentration of the hydrochloric acid in the acid is 4% by mass or more;
wherein the metal material is a stainless-steel alloy; and
wherein the electroconductive film is a two-layered film composed of a titanium film and a carbon film.
